(19) United States
(12) Patent Application Publication
(10) Pub. No.: US 2015/0372226 A1
(43) Pub. Date: Dec. 24, 2015

(54) VARIABLE SELECTIVITY SILICON GROWTH PROCESS

(71) Applicant: HGST, Inc., San Jose, CA (US)

(72) Inventors: Mac D. APODACA, San Jose, CA (US); Daniel R. SHEPARD, North Hamtpon, NH (US)

(21) Appl. No.: 14/743,132

(22) Filed: Jun. 18, 2015

Related U.S. Application Data
(60) Provisional application No. 62/014,868, filed on Jun. 20, 2014.

(51) Int. Cl. H01L 45/00

(52) U.S. Cl. CPC H01L 45/06; H01L 45/1233; H01L 45/1608; H01L 45/1675; H01L 45/1683

(57) ABSTRACT

The present invention is a means and a method for speeding up the fabrication process, lowering the cost and improving yields. The present invention is a method for manufacturing memory cells in a diode memory array by utilizing selective epitaxial growth techniques to form high quality silicon for diodes and then lesser quality silicon to fill recesses and prepare the surface for subsequent planarization or etching steps.

### CROSS-REFERENCE TO RELATED APPLICATIONS

This application claims benefit of U.S. Provisional Patent Application Ser. No. 62/014,868, filed Jun. 20, 2014, which is herein incorporated by reference. This application makes reference to U.S. Pat. No. 8,455,298 to Apodaca et al. titled “Method For Forming Self-aligned Phase Change Semiconductor Diode Memory” that issued on Jun. 4, 2013 and is incorporated herein by reference in its entirety.

### BACKGROUND OF THE INVENTION

1. Field of the Invention

In various embodiments, the present invention relates to methods for forming memory cells, and in particular for forming self-aligned diode array memory cells.

2. Description of the Related Art

As advances continue to be made in the area of semiconductor memory devices, high capacity and low cost will be increasingly important.

### SUMMARY OF THE INVENTION

The present invention is a means and a method for speeding up the fabrication process and lowering cost. The present invention is a method for manufacturing memory cells in a diode memory array by epitaxially growing silicon for high quality diodes. The present invention will be useful for reducing the amount of time taken to grow this epi-silicon on a wafer as a part of forming diodes in a cross-point diode memory array. By reducing the time for this process step, the amortized cost contribution of this deposition step is reduced while the throughput of the silicon deposition tool is increased.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawing, in which:

FIG. 1 depicts a hole into which silicon will be grown.

FIG. 2 depicts the result of silicon growth according to a prior art solution.

FIG. 3 depicts the result of silicon growth according to various embodiments of the present invention.

### DETAILED DESCRIPTION

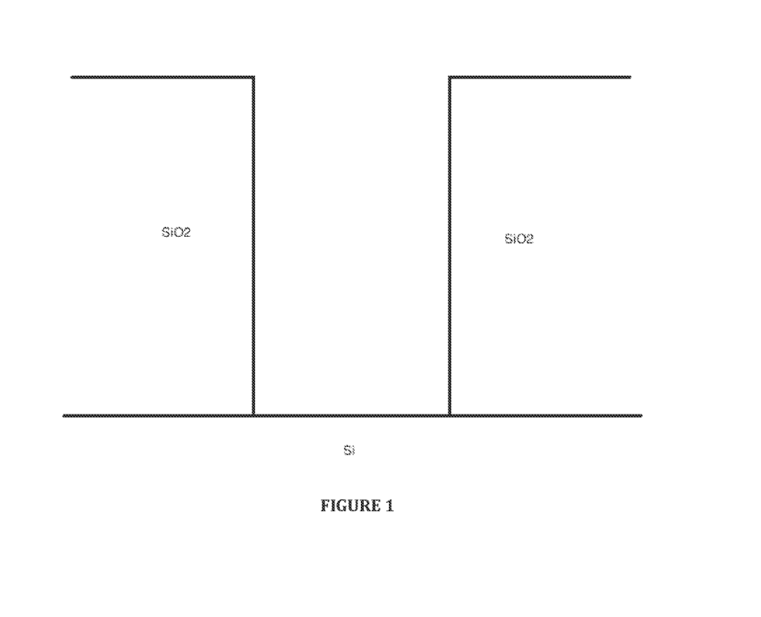

U.S. Pat. No. 8,455,298 by Apodaca et al. describes a memory cell fabrication process in which a memory cell is formed in a high aspect ratio hole. This hole is formed in a dielectric material, the bottom of which exposes a bitline comprising silicon. FIG. 1, illustrates such a high aspect ratio hole. Into this high aspect ratio hole, a current steering device, such as a diode (but could be another current steering device, transistor, a four layer diode or SCR, or the like), is formed and then, in series with this current steering device is formed an information storage element (such as a phase change element, a resistive RAM element, a memresistor, or some other element capable of storing one or more bits of information). These are well known and understood to those skilled in the art.

Into this high aspect ratio hole, semiconducting material (such as silicon) is deposited, or more to the point, is selectively grown in the hole. Such selective growth is well known to those skilled in the art. (Many other material choices are available and include other Group IV material than silicon such as germanium as well as Group III-V materials such as GaAs containing gallium and arsenic). Generally speaking, silicon is grown at an elevated temperature using a silicon source gases such as dichlorosilane, silane, or some other silicon containing gas. To affect this selective growth, this silicon source gas is combined with an etchant (in gaseous form) such as hydrochloric acid (HCl). The etchant gas will simultaneously etch silicon as that silicon is deposited. Where silicon is deposited on a non-silicon surface, the silicon deposited is amorphous in nature and easily removed by the etchant gas. However, where silicon is deposited on a crystalline silicon surface, the crystalline bonds of the lattice hold more strongly to the deposited silicon atoms and those silicon atoms are less easily removed (etched) from that surface. To be more specific, at a temperature above the dissociation temperature and a pressure between atmospheric and low pressure, a source gas is introduced along with an etchant gas. The elevated temperature cracks the source gas (i.e., separates the components of the source gas) such as dichlorosilane (SiCl₂H₂) into free Si (the Cl₂ and H₂ typically stays intact) or such as silane (SiH₄) into free Si. In addition, the etchant gas such as HCl is separated into free H and Cl atoms. The free H and the free Cl atoms combined with deposited, loosely held silicon to form SiH and SiCl (both SiH and SiCl are gaseous due to the elevated temperatures and/or low pressure) and are evacuated from the chamber.

With silicon epitaxy, for example, the silicon deposited on existing silicon is more strongly bonded than silicon deposited on non-silicon surfaces and does not easily react with the etchant elements (e.g., H and Cl). This is why the poly-silicon and amorphous silicon have higher etch rates than crystalline silicon and why this deposition technique is selective to growth on existing, exposed silicon surfaces. Selective deposition is typically done with a gas ratio of about 9:1 Si source to etchant (HCl) source. It is notable that as this gas ratio is reduced (e.g., as the etchant gas is reduced) the quality of the resulting silicon crystalline structure will diminish resulting in an increasing number of crystalline imperfections and “stacking faults” and a further reduction in the gas ratio will result in non-selective deposition.

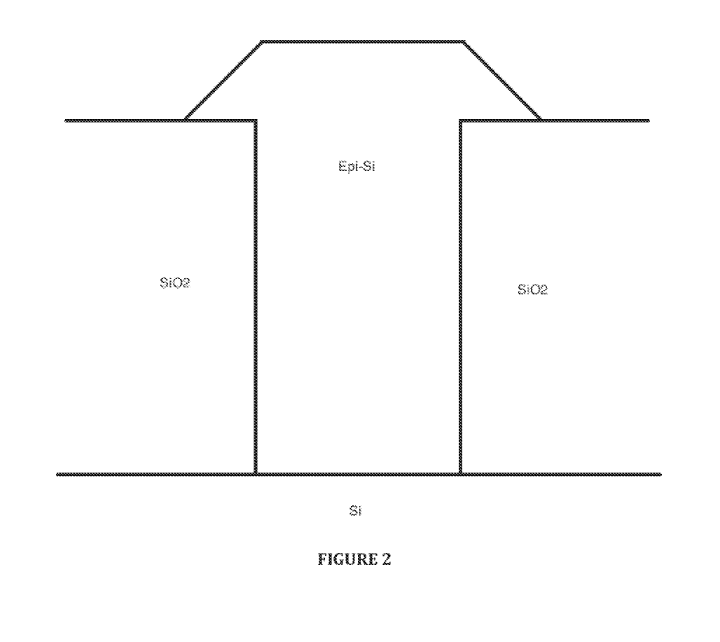

With this technique, it is possible to grow crystalline silicon selectively in surface features such as holes, trenches or a combination of holes and trenches formed within a dielectric material (such as SiO₂ or SiNₓ) on top of silicon. Silicon exposed in surface features will experience selective epi-silicon growth. When this selective silicon growth technique is employed to deposit silicon in high aspect ratio holes, as shown in FIG. 2, when the silicon reaches the top of the hole, a dome cap is formed at the surface (since the silicon growth is not constrained at the surface, it continues to grow in all directions).

However, a key disadvantage of this selective growth process is that simultaneously removing silicon as it is being deposited greatly retards the deposition rate. This reduced deposition rate means that a wafer must remain in the deposition tool for a longer time thereby reducing the throughput rate. Lower throughout has a n economic impact as the amortization of the tool is spread across fewer wafers resulting in greater amortized cost per wafer.

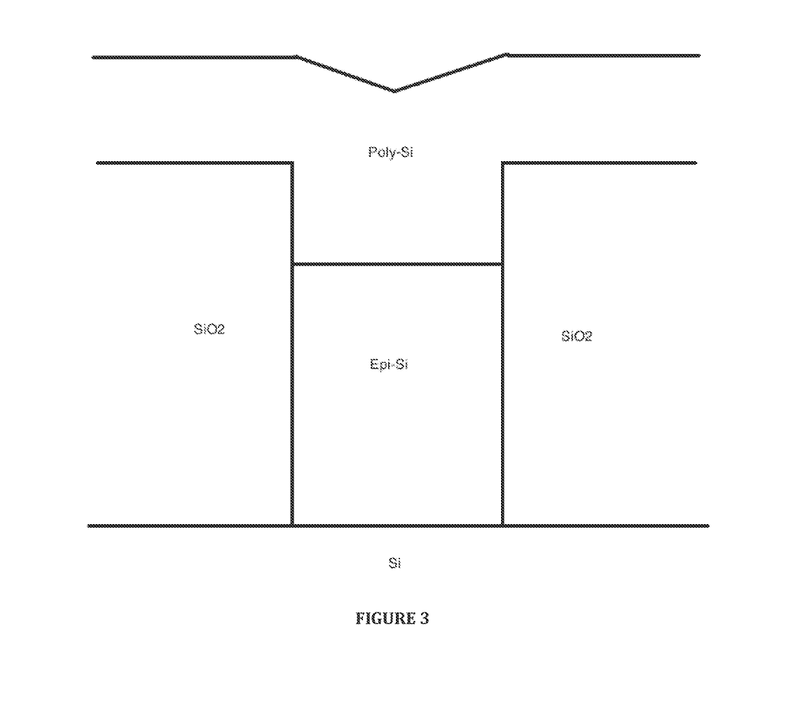

A solution to this problem, according to the present invention, is to limit the selective deposition of high quality crystalline silicon using the above described selective silicon deposition process to the portion of the formed structure that requires the higher quality, crystalline silicon and then switch the deposition to a lower quality, more rapid deposition process after that point. In other words, when the silicon thickness reaches the thickness of the desired features, reduce to turn off the etch component for faster growth. In the case of the memory cells described in U.S. Pat. No. 8,455,298 by Apodaca et al. (the '298 invention), the high aspect ratio hole is filled with a diode (requiring higher quality, crystalline silicon) in the bottom of the hole and an information storage element (where the silicon is initially a volume placeholder but is subsequently removed) in top of the hole. Other devices can require quality silicon in one area with lower quality in another (as would be the case of a diode formed in a hole where the P-N junction benefits from the higher quality but where a top ohmic contact beyond the active junction does not require high quality silicon or where a top region is subsequently removed to provide a self-aligned volume for a metal contact). In the instance of the '298 invention, the present invention can be ideally applied by utilizing the selective deposition for filling the bottom of the hole and then switching to a non-selective deposition process (e.g., turning off the etching component of the selective deposition process) to fill the top of the hole. This dual deposition technique is depicted in FIG. 3.

Features having generally similar depths and characteristics will fill at generally the same rate. However, once the features have filled and reach the surface, a mushroom-shaped dome will form above the now filled holes. This can result in a very uneven surface. To prevent this unevenness, the features can be filled near to or approximately to the surface using a selective deposition process as described above, and the switching to a secondary deposition process (this secondary, non-selective silicon deposition will deposit silicon on both surfaces of the selectively grown silicon as well as one any exposed dielectric material). This approach will work well when fabricating cross-point diode memory arrays in particular. Cross-point diode memory arrays require good quality diodes to provide high forward current to facilitate cell programming and erasing while also providing low reverse leakage current. High quality crystalline silicon is preferred for fabricating diodes having these characteristics. However, on top of these diodes will be a contact or an information storage element. During the fabrication process, the area above the diode will initially be filled with silicon during the silicon deposition process and then later be etched out to provide a cup or some form of recess into which material is then deposited to provide the functionality of an information storage element or contact. Since the silicon for the element above the diode will subsequently be removed, that portion need not be made using the same high quality silicon as that used to form the diode. As a result, the same high quality selective silicon deposition process used to form the diode does not have to be used to form the upper portion; a different deposition process that is faster, lower cost, less selective (including non-selective), poly-silicon or amorphous silicon deposition process can be used. (It is even an option to deposit a material other than silicon, although it is preferable to deposit a material that etches similarly to silicon to simplify any subsequent etch step to remove material at the top of the now filled high aspect ratio hole or feature. Also, to better facilitate this subsequent etch, it is desirable to have the surface be generally level such that the distance down that the etch will have to remove is the same everywhere, otherwise the depth of the etch will vary according to the surface topography. This level surface topography can be achieved through planarization (such as CMP), but it the surface is covered by silicon in some places and not in others, this planarization step may not achieve the desired level results (if subsequent planarization is not desired, the finishing deposition to fill the last portion of the hole can be made with either a lower quality, faster growing selective deposition or with a non-selective deposition—it a high aspect ratio remains for the last portion of the hole, a lower quality, faster growing selective deposition is preferred to prevent the hole from closing over the top before the hole is completely filled). Covering the entire surface with the same material is in the high aspect ratio holes will result in a more consistent and level surface because the high points will planarize away more quickly resulting in a smoothing of the surface; however, it the surface consists of different exposed material, this smoothing of the surface will be less effective.) The present invention will result in a deposition results that is somewhat self-leveling and that reduces certain surface imperfections in growth as well as the boldering or mushroom cap effects that an occur with a purely selective growth process.

While it is an element of the present invention to provide better economics by increasing tool throughput, it is also an element of the present invention to provide more uniform coverage of the surface to improve subsequent planarization steps (e.g., by CMP or planar etch-back) to improve yield. This faster growth process according to the present invention, growing silicon slowly for good crystalline silicon and then quickly for finishing silicon, will result in lower costs and improved yields.

Variations will come to mind. For example rather than simply reduce or eliminate the etchant gasses while keeping the silicon source gas, an entirely different silicon deposition process could be employed following the selective silicon growth process. This might be achieved by initially utilizing dichlorosilane combined with an HCl etchant to grow silicon selectively, but then switching to a non-selective silane or even a lower quality selective process to finish filling the features and provide a surface overcoat to improve subsequent planarization. Other variations can involve the rate of change to the low (or no) etchant source and this rate of change can be done either slowly or quickly. The point of transition form high quality, crystalline silicon to lower quality poly-silicon or amorphous silicon can occur at a point where any subsequent silicon removal will remove all of the non crystalline silicon or can occur at a point where a portion of the non crystalline silicon might remain (i.e., some poly or amorphous silicon may remain at the top for, for example, a better ohmic or electrical contact).

Memory device fabrication techniques according to the present invention may be applied to memory devices and systems for storing digital text, digital books, digital music (such as MP3 layers and cellular telephones), digital audio, digital photographs (wherein one or more digital still images may be stored including sequences of digital images), digital video (such as personal entertainment devices), digital cartography (wherein one or more digital maps can be stored, such as GPS devices), and any other digital or digitized information as well as any combinations thereof. Devices incorporated embodiments of the present invention may be embedded or removable, and may be interchangeable among other devices that can access the data therein. Embodiments of the invention may be packaged in any variety of industry-standard form factor, including Compact Flash, Secure Digital, MultiMedia Cards, PCMCIA Cards, Memory stick, any of a large variety of integrated circuit packages including Ball Grid Arrays, Dual In0Line Packages (DIPs), SOICs, PLCC, TQFPs and the like, as well as in proprietary form factors and custom design packages. These packages may contain just the memory chip, multiple memory chips, one or more memory chips along with other logic devices or other storage devices such as PLDs, PLAs, micro-controllers, microprocessors, controller chips or chip-sets or other custom or standard circuitry.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

1. A method for depositing semiconducting material, comprising:
(i) providing a layer of dielectric material on a crystalline semiconductor substrate;
(ii) creating features in the dielectric material that expose the substrate;
(iii) selectively growing a first semiconducting material on the exposed substrate; and
(iv) growing a second semiconducting material either on the exposed first semiconducting material using a low quality selective deposition process or on the exposed first semiconducting material and the exposed dielectric material using a non-selective deposition process.

2. The method of claim 1, further comprising removing all or a portion of the second semiconducting material either by etching or by planarization.

3. The method of claim 1, further comprising forming a recess in the surface by removing at least a portion of the second semiconducting material.

4. The method of claim 3, whereby the recess is filled in with either a contact material or an information storage material.

5. The method of claim 1, whereby the crystalline semiconductor substrate comprises group IV semiconductor material.

6. The method of claim 1, whereby the grown semiconductor material comprises a group IV semiconductor material.

7. The method of claim 1, whereby the crystalline semiconductor substrate comprises group III-V semiconductor material.

8. The method of claim 1, whereby the grown semiconductor substrate material comprises group III-V semiconductor material.

9. The method of claim 5, whereby the group V semiconductor material comprises one or more from the list of silicon and germanium.

10. The method of claim 6, whereby the group IV semiconductor material comprises one or more from the list of silicon and germanium.

11. The method of claim 7, whereby the group III-IV semiconductor material comprises one or more from the list of gallium and arsenic.

12. The method of claim 8, whereby the group III-IV semiconductor material comprises one or more from the list of gallium and arsenic.

13. A method for forming a memory cell, comprising:
forming a layer of dielectric material on a crystalline semiconductor substrate;
creating a recess in the dielectric material that exposes the substrate;
selectively growing a first semiconducting material on the exposed substrate, wherein the first semiconducting material is grown at a first growth rate; and
growing a second semiconducting material on the exposed first semiconducting material, wherein the second semiconducting material is grown at a second growth rate that is greater than the first growth rate.

14. The method of claim 13, wherein the crystalline semiconductor substrate comprises a group IV semiconductor material.

15. The method of claim 14, wherein the grown semiconductor material comprises a group IV semiconductor material.

16. The method of claim 13, wherein the crystalline semiconductor substrate comprises a group III-V semiconductor material.

17. The method of claim 16, wherein the grown semiconductor substrate material comprises a group III-V semiconductor material.

18. A memory element, comprising:
a layer of dielectric material disposed on a crystalline semiconductor substrate, wherein the dielectric layer has a recess formed therethrough exposing the substrate;
a first semiconducting material disposed in the recess and on the exposed substrate; and
a second semiconducting material disposed on the first semiconducting material, wherein the second semiconducting material has at least one property that is different than the first semiconducting material.

19. The memory element of claim 18, wherein the crystalline semiconductor substrate comprises a group IV semiconductor material.

20. The memory element of claim 19, wherein the first and second semiconductor materials comprise a group IV semiconductor material.
